(19) United States
(12) Patent Application Publication
(10) Pub. No.: US 2019/0238144 A1
(43) Pub. Date: Aug. 1, 2019

(54) ADC Based PLL

(71) Applicant: Integrated Device Technology, Inc., San Jose, CA (US)

(72) Inventor: Brian BUELL, Gilbert, AZ (US)

(21) Appl. No.: 16/261,260

(22) Filed: Jan. 29, 2019

Related U.S. Application Data
(60) Provisional application No. 62/624,440, filed on Jan. 31, 2018.

(51) Int. Cl. H03L 7/099; H03M 1/12

(52) U.S. Cl. CPC H03L 7/099; H03M 1/1245

(57) ABSTRACT

A phase-locked-loop (PLL) is presented. An embodiment of the PLL includes an analog-to-digital converter (ADC) receiving and digitizing a signal from a crystal oscillator; a digital circuit processing the digitized signal from the ADC in comparison with an output signal of the PLL to provide control signals; and a digitally-controlled oscillator providing the output signal in response to the control signals from the digital circuit.

### RELATED APPLICATIONS

This disclosure claims priority to U.S. Provisional Application Ser. No. 62/624,440, entitled “ADC Based PLL,” filed on Jan. 31, 2018, which is herein incorporated by reference in its entirety.

### TECHNICAL FIELD

Embodiments of the present invention are related to phase locked loops (PLLs) and, in particular, to PLLs based on an ADC.

### DISCUSSION OF RELATED ART

In general, a PLL is a feedback loop that includes a phase detector that receives an input signal, a loop filter, and a voltage-controlled oscillator (VCO) that outputs a signal in response to the input signal. The phase detector generates an error signal related to the difference in phase between the output signal and the input signal. The loop filter can provide an almost DC level output voltage that is related to the error signal generated by the phase detector. The output signal from the VCO provides a signal that follows the input signal.

Consequently, PLLs are electronic circuits with a voltage or voltage-driven oscillator that constantly adjusts to match the frequency of an input signal. PLLs are used to generate, stabilize, modulate, demodulate, filter or recover a signal from a “noisy” communications channel. PLLs are used in multiple areas, including telecommunications, computers, radio, and other electronic applications. However, traditional PLL circuits suffer from poor performance due to a bandwidth that is limited to a fraction of the reference frequency and multiplication of reference noise.

Therefore, there is a need to develop better performing PLL circuits.

### SUMMARY

In some embodiments, a phase-locked-loop (PLL) is provided. In accordance with some embodiments, the PLL includes an analog-to-digital converter (ADC) receiving and digitizing a signal from a crystal oscillator; a digital circuit processing the digitized signal from the ADC in comparison with an output signal of the PLL to provide control signals; and a digitally-controlled oscillator providing the output signal in response to the control signals from the digital circuit.

### BRIEF DESCRIPTION OF THE FIGURES

FIG. 1 illustrates a conventional PLL.

FIG. 2 illustrates another conventional PLL.

FIG. 3 illustrates a PLL according to some embodiments of the present invention.

FIG. 4 illustrates a PLL as illustrated in FIG. 3.

These and other aspects of the present invention are further discussed below.

### DETAILED DESCRIPTION

In the following description, specific details are set forth describing some embodiments of the present invention. It will be apparent, however, to one skilled in the art that some embodiments may be practiced without some or all of these specific details. The specific embodiments disclosed herein are meant to be illustrative but not limiting. One skilled in the art may realize other elements that, although not specifically described here, are within the scope and the spirit of this disclosure.

This description illustrates inventive aspects and embodiments should not be taken as limiting—the claims define the protected invention. Various changes may be made without departing from the spirit and scope of this description and the claims. In some instances, well-known structures and techniques have not been shown or described in detail in order not to obscure the invention.

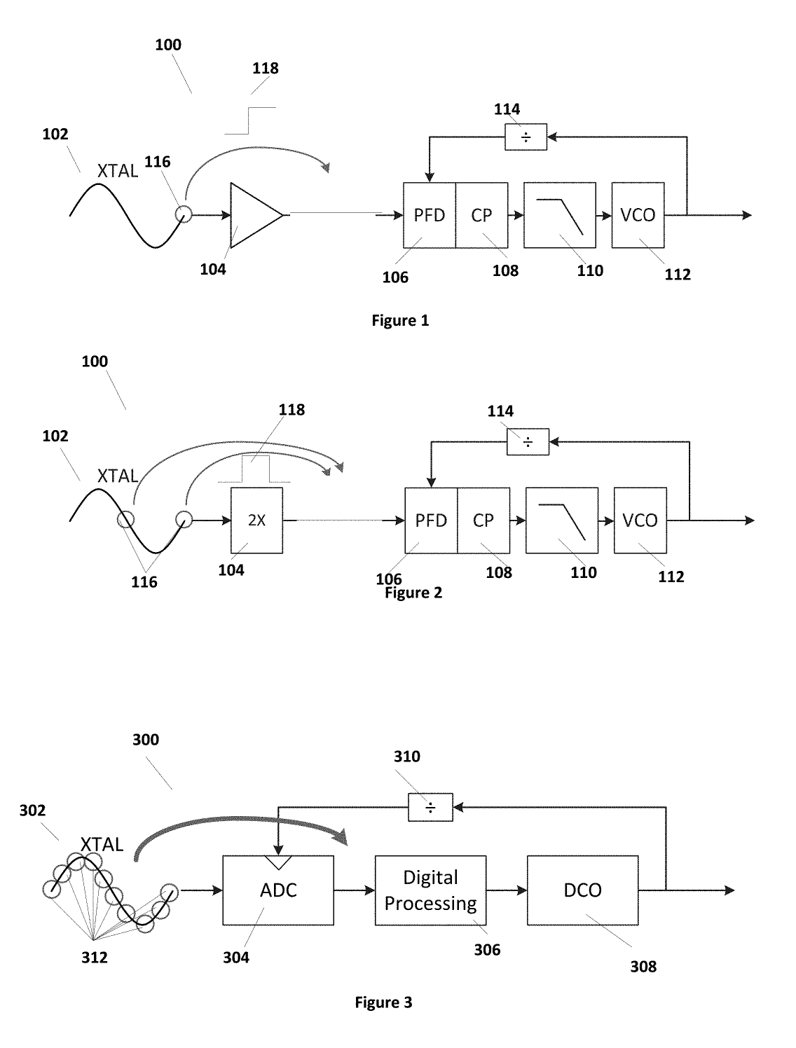

Traditional PLL architectures suffer from poor performance due to a bandwidth that is limited to a fraction of the reference frequency and multiplication of reference floor noise. Traditional PLLs are “edge” based, operating on rising and/or falling edges of a reference clock signal. Examples of these systems are illustrated in FIGS. 1 and 2.

FIG. 1 illustrates a traditional PLL architecture 100. In a traditional PLL architecture, phase error is sampled by a phase and frequency determiner only once per reference period, usually on the rising edge of the reference clock. Phase information from the crystal oscillator (XTAL) signal is ignored during most of the reference cycle. As is illustrated in FIG. 1, a waveform 102 from a crystal oscillator (XTAL) is input to a sample and hold 104. Sample and hold 104 in FIG. 1 samples on the rising edge of reference clock signal 118. The sampled output signal from sample and hold 104 is input to a phase and frequency determination (PFD) 106, which provides a signal to charge pump (CP) 108. The output from CP 108 is input to low-pass filter 110, which provides a signal to voltage-controlled oscillator (VCO) 112. The output of VCO 112, which is the output signal from PLL 100, is input to frequency divider 114, which is used as an input to PFD 106. PFD 106 determines the frequency error and phase error of the signal from sample and hold 104 by comparison with the signal from divider 114. As such, the frequency and phase of the output signal from VCO 112 can be adjusted according to the phase error between the signal from sample and hold 104 and the input from divider 114.

As illustrated in FIG. 1, traditional PLLs are “edge” based, sampling on the rising edge of reference clock signal 118. It has become common in modern designs to sample phase error twice each clock cycle, on both the rising and the falling edges of the reference clock. Such a practice reduces noise multiplication of the reference floor, reduces the delta-sigma noise in fractional PLLs, and allows higher PLL bandwidths. FIG. 2 provides an example of this PLL architecture, where sample and hold 104 samples two sample points 116, one on the rising edge and one on the falling edge of the sample clock 118. Traditional PLLs can only extract phase and frequency information from the XTAL oscillator at “zero-crossing” points of the oscillator. However, this additional sampling does not alleviate the issues raised with conventional PLLs.

FIG. 3 illustrates a PLL architecture 300 according to some embodiments of the present invention. In accordance with some embodiments, an analog-to-digital converter (ADC) based PLL samples the XTAL signal 302 phase several times each reference period. Such an increased sampling rate enables a highly digital solution for the PLL which can have excellent performance. As illustrated in FIG. 3, XTAL signal 302 is input to an ADC 304, which samples XTAL multiple times during a reference times. As illustrated in FIG. 3, XTAL signal 302 is sampled at sampling points 312. ADC 304 may be a high speed ADC capable of sampling the XTAL signal multiple times during each reference time period. As illustrated in FIG. 304, ADC 304 can be clocked by the output of digitally-controlled oscillator (DCO) 308, or by a divided output signal from DCO 308. In some embodiments, an external clock may be used with ADC 304.

As is illustrated in FIG. 3, the sampling data obtained by ADC 304 is input to digital processing 306. Digital processing 306 can include a high speed digital processor that determines phase and frequency errors digitally and provides the appropriate signal to DCO 308 to provide an appropriate output signal. Consequently, digital processing circuit 306 adjusts the DCO frequency to lock it to the XTAL signal 302. The output signal can be frequency divided in divider 310 prior to being input to ADC 304.

Digital processing 306 can include a processor, memory (both volatile and non-volatile), and supporting circuitry. Digital processing 306 includes components sufficient to execute software to analyze signals from ADC 304 and provide control signals to DCO 308 as described. In some embodiments, digital processing 306 may include digital circuitry so that the processing of signals from ADC 304 is performed mostly by dedicated digital devices.

Digital processing 306 takes the output signal from ADC 304, determines the phase error between the output signal from DCO 308 and the signal from ADC 304, and applies a correction to DCO 308 to correct for the error. As such, the signal from frequency divider 310 may either by digitized in ADC 304 or the control signal from digital processing 306 can be input to ADC 304 for comparison with the digitized values of the XTAL signal 312.

PLL architecture 300 as illustrated in FIG. 3 provides for a number of benefits. PLL architecture 300 reduces noise multiplication of the reference floor. Maximum PLL bandwidth is limited only by the high-speed ADC, not the slower XTAL frequency. PLL architecture 300 further allows new fractional synthesis techniques to manage spurious tones. Further, the highly digital architecture benefits from technology scaling.

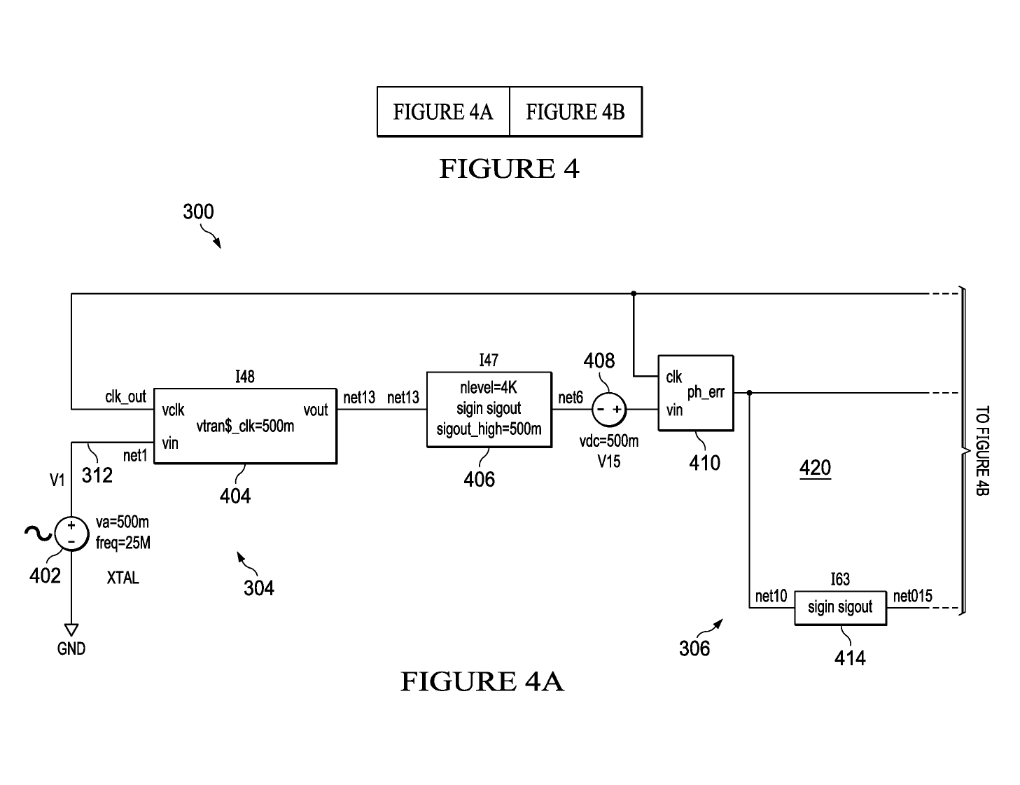

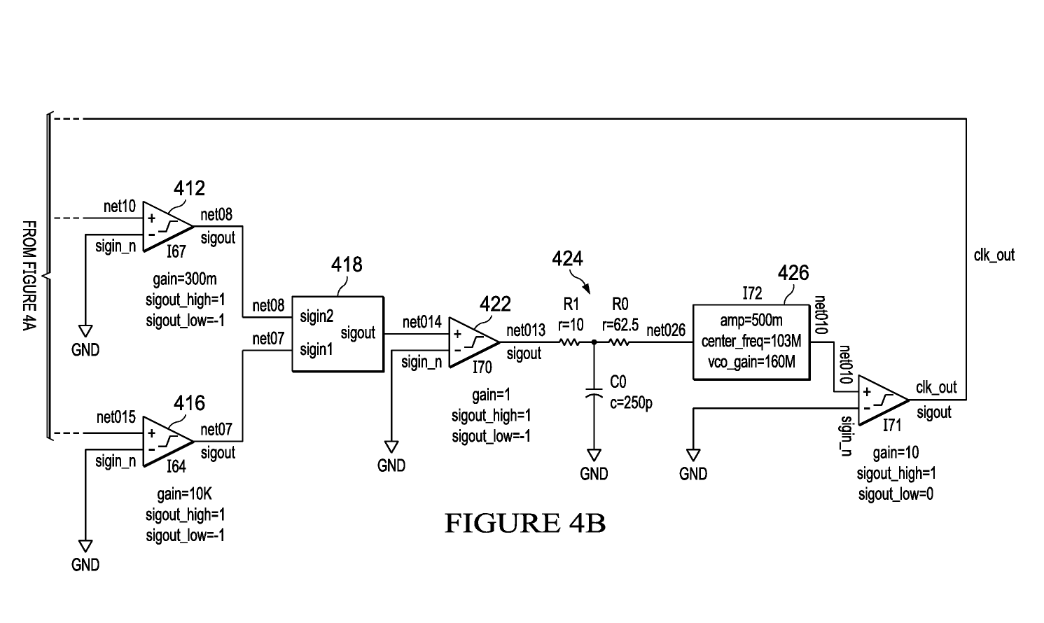

FIG. 4 illustrates an example embodiment of architecture 300 and illustrates the operation of ADC 304 and digital processing 306. The processing depicted in FIG. 4 can be implemented in hardware or may be implemented in firmware by a processor executing stored instructions.

As is illustrated in FIG. 4, XTAL signal 312 can be generated XTAL generator 402. Although XTAL generator 402 can generate any frequency signal of any amplitude, in one specific example, XTAL generator 402 can generate a 25 MHz signal at a 500 mV amplitude. ADC 304 includes sample and hold circuit 404 and quantizer 406. The signal from XTAL generator 402 is captured by sample and hold circuit 404, which receives a clock input from the output signal from PLL 300. The output signal from sample and hold 404 is input to quantizer 406. In some embodiments, quantizer 406 may be a 4000 level quantizer. Signal offset can be added by a voltage supply 408. The signal is then processed through digital processing 306, which calculates and processes the phase error.

As illustrated in FIG. 4, a phase error detector 410 of digital processing 306 determines the phase error between the digitized output signal from quantizer 406 and the signal output from PLL 300. The illustrated in FIG. 4 does not include frequency divider 310, although some embodiments will include frequency divider 310. The output signal from phase detector 410 is input to digital circuit 420, which includes amplifier 412, integrator 414, and amplifier 416. As is illustrated in FIG. 4, the phase error signal from phase error detector 410 is input to amplifier 412. Further, the phase error signal from phase error detector 410 can be input to integrator 414, the output of which is input to amplifier 416.

The output signals from amplifiers 412 and 416 are input to adder 418. The output signal from adder 418 is amplified in amplifier 422 and filtered in filter 424 before being input to VCO 426. The digital-controlled VCO 426 provides the signal output, which may be amplified by an amplifier 428 to provide the output signal.

In some embodiments, quantizer 406 and sample and hold circuit 404 form a 12 bit ADC operating at 125. Msps. As discussed above, the XTAL signal is a 25 MHz signal from an ideal sine wave reference generator 402. Further, VCO noise from an existing production design can be inserted at generator 408.

The above detailed description is provided to illustrate specific embodiments of the present invention and is not intended to be limiting. Numerous variations and modifications within the scope of the present invention are possible. The present invention is set forth in the following claims.

What is claimed is:

1. A phase-locked-loop (PLL), comprising:
an analog-to-digital converter (ADC) receiving and digitizing an input signal;
a digital circuit processing the digitized signal from the ADC in comparison with an output signal of the PLL to provide control signals; and
a digitally-controlled oscillator providing an output signal in response to the control signals from the digital circuit.

2. The PLL of claim 1, wherein the output signal follows the input signal.

3. The PLL of claim 1, wherein the input signal is provided by a crystal oscillator.

4. The PLL of claim 1, wherein the ADC samples the input signal at a plurality of sample points over a period of the input signal.

5. The PLL of claim 1, further including a frequency divider coupled between the output signal and the digital circuit.

6. The PLL of claim 1, wherein the ADC includes a sample and hold circuit and a quantizer.

7. The PLL of claim 1, wherein the digital circuit includes a phase error circuit that compares a signal from the ADC with the output signal to generate a phase error.

8. The PLL of claim 7, wherein the digital circuit generates the control circuit in response to the phase error.

9. A method of performing a phase-locked-loop (PLL), comprising:
receiving an input signal;
digitizing the input signal in an analog-to-digital converter (ADC) at a plurality of sample points over a period of the input signal;
generating a control signal based on digitized signal from the ADC and an output signal from the PLL;
generating an output signal in a voltage-controlled oscillator (VCO) based on the control signal.

10. The method of claim 9, wherein the output signal follows the input signal.

11. The method of claim 9, wherein the input signal is provided by a crystal oscillator.

12. The method of claim 9, wherein the ADC samples the input signal at a plurality of sample points over a period of the input signal.

13. The method of claim 9, further including a frequency dividing the output signal.

14. The method of claim 9, wherein digitizing includes sampling and quantizing.

15. The method of claim 9, wherein generating a control signal includes determining a phase error between the input signal and the output signal.

16. The method of claim 15, wherein the control signal is determined based on the phase error.
